(19) United States
(12) Patent Application Publication
(10) Pub. No.: US 2010/0133699 A1
(43) Pub. Date: Jun. 3, 2010

(54) MICROSTRUCTURE DEVICE INCLUDING A METALLIZATION STRUCTURE WITH AIR GAPS FORMED COMMONLY WITH VIAS

(76) Inventors: Thomas Werner, Moritzburg (DE); Kai Frohberg, Niederau (DE); Frank Feustel, Dresden (DE)

Correspondence Address: Advanced Mirco Devices, Inc.;c/o Williams, Morgan & Amerson, 10333 Richmond, Suite 1100, Houston, TX, 77042, US

(21) Appl. No.: 12/619,816

(22) Filed: Nov. 17, 2009

(30) Foreign Application Priority Data
Nov. 28, 2008 (DE) 10 2008 059 499.7

(51) Int. Cl. H01L 23/48; H01L 21/768

(52) U.S. Cl. 257/774; 438/637; 257/E23.011; 257/E21.585

(57) ABSTRACT

Air gaps may be formed in a metallization layer of a microstructure device on the basis of a patterning sequence in which respective via openings are also formed. Thereafter, the via openings and the air gaps may be closed by a deposition process without significantly affecting the interior of the corresponding openings. Thereafter, the further processing may be continued by forming respective trenches while maintaining integrity of the covered air gaps. Thus, the relative permittivity of the interlayer dielectric material may be efficiently reduced without adding additional process complexity.

### BACKGROUND OF THE INVENTION

1. Field of the Invention

Generally, the subject matter of the present disclosure relates to microstructure devices, such as integrated circuits, and, more particularly, to metallization layers including highly conductive metals, such as copper, embedded into a dielectric material of reduced permittivity.

2. Description of the Related Art

In modern integrated circuits, minimum feature sizes, such as the channel length of field effect transistors, have reached the deep sub-micron range, thereby steadily increasing performance of these circuits in terms of speed and/or power consumption and/or diversity of circuit functions. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines and the spaces between the metal lines have to be reduced to compensate for a reduced amount of available floor space and for an increased number of circuit elements provided per unit area.

In integrated circuits having minimum dimensions of approximately 0.35 μm and less, a limiting factor of device performance is the signal propagation delay caused by the switching speed of the transistor elements. As the channel length of these transistor elements has now reached 50 nm and less, the signal propagation delay is no longer limited by the field effect transistors but is limited, owing to the increased circuit density, by the interconnect lines, since the line-to-line capacitance (C) is increased and also the resistance (R) of the lines is increased due to their reduced cross-sectional area. The parasitic RC time constants and the capacitive coupling between neighboring metal lines therefore require the introduction of a new type of materials for forming the metallization layer.

Traditionally, metallization layers, i.e., the wiring layers including metal lines and vias for providing the electrical connection of the circuit elements according to a specified circuit layout, are formed by a dielectric layer stack including, for example, silicon dioxide and/or silicon nitride with aluminum as the typical metal. Since aluminum suffers from significant electromigration at higher current densities that may be necessary in integrated circuits having extremely scaled feature sizes, aluminum is being replaced by, for instance, copper, which has a significantly lower electrical resistance and a higher resistivity against electromigration. For highly sophisticated applications, in addition to using copper and/or copper alloys, the well-established and well-known dielectric materials silicon dioxide (k≈4.2) and silicon nitride (k>7) may increasingly be replaced by so-called low-k dielectric materials having a relative permittivity of approximately 3.0 and less. However, the transition from the well-known and well-established aluminum/silicon dioxide metallization layer to a copper-based metallization layer possibly in combination with a low-k dielectric material is associated with a plurality of issues to be dealt with.

For example, copper may not be deposited in relatively high amounts in an efficient manner by well-established deposition methods, such as chemical and physical vapor deposition. Moreover, copper may not be efficiently patterned by well-established anisotropic etch processes. Therefore, the so-called damascene or inlaid technique is frequently employed in forming metallization layers including copper lines and vias. Typically, in the damascene technique, the dielectric layer is deposited and then patterned for receiving trenches and via openings that are subsequently filled with copper or alloys thereof by plating methods, such as electroplating or electroless plating. Moreover, since copper readily diffuses in a plurality of dielectrics, such as silicon dioxide and in many low-k dielectrics, the formation of a diffusion barrier layer at interfaces with the neighboring dielectric material may be required. Additionally, the diffusion of moisture and oxygen into the copper-based metal has to be suppressed as copper readily reacts to form oxidized portions, thereby possibly deteriorating the characteristics of the copper-based metal line with respect to adhesion, conductivity and the resistance against electromigration.

During the filling in of a conductive material, such as copper, into the trenches and via openings, a significant degree of overfill has to be provided in order to reliably fill the corresponding openings from bottom to top without voids and other deposition-related irregularities. Consequently, after the metal deposition process, excess material may have to be removed and the resulting surface topography is to be planarized, for instance by using electrochemical etch techniques, chemical mechanical polishing (CMP) and the like. For example, during CMP processes, a significant degree of mechanical stress may be applied to the metallization levels formed so far, which may cause structural damage to a certain degree, in particular when sophisticated dielectric materials of reduced permittivity are used. As previously explained, the capacitive coupling between neighboring metal lines may have a significant influence on the overall performance of the semiconductor device, in particular in metallization levels, which are substantially “capacitance driven,” i.e., in which a plurality of closely spaced metal lines have to be provided in accordance with device requirements, thereby possibly causing signal propagation delay and signal interference between neighboring metal lines. For this reason, so-called low-k dielectric materials or ultra low-k materials may be used, which may provide a dielectric constant of 3.0 and significantly less, in order to enhance the overall electrical performance of the metallization levels. On the other hand, typically, a reduced permittivity of the dielectric material is associated with a reduced mechanical stability, which may require sophisticated patterning regimes so as to not unduly deteriorate reliability of the metallization system.

The continuous reduction of the feature sizes, however, with gate lengths of approximately 40 nm and less, may demand even more reduced dielectric constants of the corresponding dielectric materials, which may increasingly contribute to yield loss due to, for instance, insufficient mechanical stability of respective ultra low-k materials. For this reason, it has been proposed to introduce “air gaps,” at least at critical device areas, since air or similar gases may have a dielectric constant of approximately 1.0, thereby providing a reduced overall permittivity, while nevertheless allowing the usage of less critical dielectric materials. Hence, by introducing appropriately positioned air gaps, the overall permittivity may be reduced while nevertheless the mechanical stability of the dielectric material may be superior compared to conventional ultra low-k dielectrics. For example, it has been proposed to introduce nano holes into appropriate dielectric materials which may be randomly distributed in the dielectric material to significantly reduce the density of the dielectric material. However, the creation and distribution of the respective nano holes may require a plurality of sophisticated process steps for creating the holes with a desired density, while at the same time the overall characteristics of the dielectric material may be changed in view of the further processing, for instance with respect to planarizing surface areas, depositing further materials and the like.

In other approaches, advanced lithography processes are additionally introduced to create appropriate etch masks for forming gaps near respective metal lines with a position and size as defined by the lithographically formed etch mask. In this case, however, additional cost intensive lithography steps may be required.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to methods and devices in which air gaps may be positioned between metal regions in sophisticated metallization systems, thereby enabling the reduction of the overall permittivity in a reliable and reproducible manner while nevertheless avoiding cost-intensive additional sophisticated lithography processes. For this purpose, the air gaps may be formed in a dielectric material of the metallization system together with openings, such as via openings, which may have to be patterned by a further lithography process in which the previously formed air gaps may not be affected so that a high degree of compatibility with conventional patterning regimes may be maintained, while nevertheless providing the desired air gaps. Prior to further processing previously formed air gaps and the via openings, in some illustrative aspects disclosed herein, a non-masked deposition step may be performed to appropriately “seal” the via openings and the air gaps, wherein the sealing may be substantially maintained throughout the further processing of the semiconductor device. Consequently, appropriate dielectric materials providing the desired characteristics may be used while the reliable and reproducible formation of the air gaps at critical device areas in the metallization level may enable an adjustment of the overall permittivity in accordance with device requirements. For example, the metallization levels of integrated circuits including circuit elements of critical dimensions of approximately 40 nm and less may be manufactured with reduced permittivity, at least locally, while in total the mechanical integrity of the metallization level under consideration may be enhanced by avoiding extremely sophisticated and sensitive low-k dielectric materials.

One illustrative method disclosed herein comprises forming a via opening and an air gap in a first dielectric layer of a metallization system of a semiconductor device in a common etch process. The method further comprises depositing a second dielectric layer to cover the via opening and the air gap. Moreover, a depth of the via opening is increased to extend to a conductive region formed below the first dielectric layer while maintaining the air gap. Finally, the via opening is filled with a metal-containing material.

A further illustrative method disclosed herein comprises forming an etch mask above a dielectric material of a metallization layer of a microstructure device, wherein the dielectric material comprises a first cavity covered by a first portion of the dielectric material and a second cavity covered by a second portion of the dielectric material, wherein the etch mask exposes the first portion and covers the second portion of the dielectric material. The method additionally comprises selectively opening the first cavity by using the etch mask and filling the first cavity with a metal-containing material.

One illustrative microstructure device disclosed herein comprises a first dielectric layer of a metallization layer and a second dielectric layer formed on the first dielectric layer. Moreover, the device comprises a metal line formed in the second dielectric layer so as to extend into the first dielectric layer. Additionally, an air gap is formed in the first dielectric layer and is capped by the second dielectric layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a microstructure device, for instance an integrated circuit comprising a metallization system, which is to receive air gaps between adjacent metal lines during various manufacturing stages, according to illustrative embodiments;

FIG. 1c schematically illustrates a top view of a portion of the metallization system of the device of FIGS. 1a-1b, according to illustrative embodiments;

FIGS. 1d-1e schematically illustrate cross-sectional views of the semiconductor device during the deposition of a cap material for covering via openings and air gaps, according to illustrative embodiments;

FIGS. 1f-1i schematically illustrate cross-sectional views of the microstructure device during various manufacturing stages in forming metal lines and vias in combination with corresponding air gaps, according to illustrative embodiments;

FIG. 1j schematically illustrates a top view of the metallization level under consideration in a substantially completed state; and

FIGS. 1k-1l schematically illustrate cross-sectional views of the microstructure device during a patterning sequence for forming a trench above a via opening while maintaining an air gap, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides techniques and microstructure devices, for instance integrated circuits, in which electrical performance of a metallization system may be enhanced by providing air gaps in the vicinity of critical metal regions, such as metal lines, without requiring additional lithography processes. That is, the positioning and the dimensioning of the air gaps may be accomplished during the manufacturing flow for forming via openings and corresponding trenches for the metallization level under consideration without using additional lithography steps, thereby substantially not unduly contributing to overall process complexity. Consequently, the position and the shape of the air gaps may be defined on the basis of a lithography sequence in which also corresponding via openings may be provided so that the corresponding shapes and dimensions of the air gaps may be adapted to the critical dimensions that may have to be used for patterning the metallization level under consideration. In some illustrative embodiments, the layout of the corresponding metallization level may be appropriately adapted with respect to the capabilities of the lithography process under consideration in order to position a corresponding air gap adjacent to critical metal lines if an overall reduced capacitance is required. Consequently, the via openings and the air gaps may be provided on the basis of a single lithography mask, wherein the actual “distinction” between via openings and air gaps may be accomplished by a subsequent lithography step used to define corresponding trenches for the metal line of the metallization level under consideration. For this purpose, the via openings and air gaps may be “covered” by a dielectric material in such a manner that a significant interior volume of the corresponding openings may be maintained, which may be accomplished with appropriately designed deposition techniques, so that the permittivity reducing effect of the air gaps may be substantially maintained without being affected by providing the cap material. During the subsequent processing, the integrity of the air gaps, capped or covered by the additional dielectric material, may be maintained by an etch mask which defines the position and the size of the corresponding trenches for the metal lines to be formed. Consequently, the additional dielectric material used for closing the via openings and the air gaps may be used as a part of the interlayer dielectric material of the metallization layer in which the corresponding trenches and metal lines may be formed during the subsequent patterning wherein, depending on the overall device requirements, the trenches may extend into the dielectric material including the via openings and the air gaps. After providing the corresponding trenches, the further processing may be continued with a high degree of compatibility with well-established process techniques in filling in an appropriate metal, wherein, however, contrary to conventional strategies, a portion of the interlayer dielectric material may reliably maintain integrity of the previously formed air gaps. Consequently, a reliable and reproducible positioning and dimensioning of the air gaps may be accomplished, thereby reducing yield loss that may conventionally be associated with critical material characteristics of ultra low-k dielectric material, while with respect to other conventional strategies, additional complex and sophisticated lithography steps may be avoided.

It should be appreciated that the present disclosure may be advantageously applied to microstructure devices, such as integrated circuits, in which critical device features, such as dimensions of transistor elements and the like, may be on the order of magnitude of 50 nm and significantly less since, in these cases, sophisticated metallization systems are typically required in which the moderately high number of individual metallization layers may result in a reduced mechanical stability, as previously explained. Hence, the parasitic capacitance may be efficiently reduced substantially without additional process complexity. However, the principles disclosed herein may also be readily applied to less critical applications in which the incorporation of air gaps into the metallization system may result in enhanced performance, thereby possibly allowing the omission of sophisticated low-k dielectric materials. Consequently, the present disclosure should not be considered as being restricted to specific critical device dimensions unless such restrictions are explicitly set forth in the appended claims or the specification.

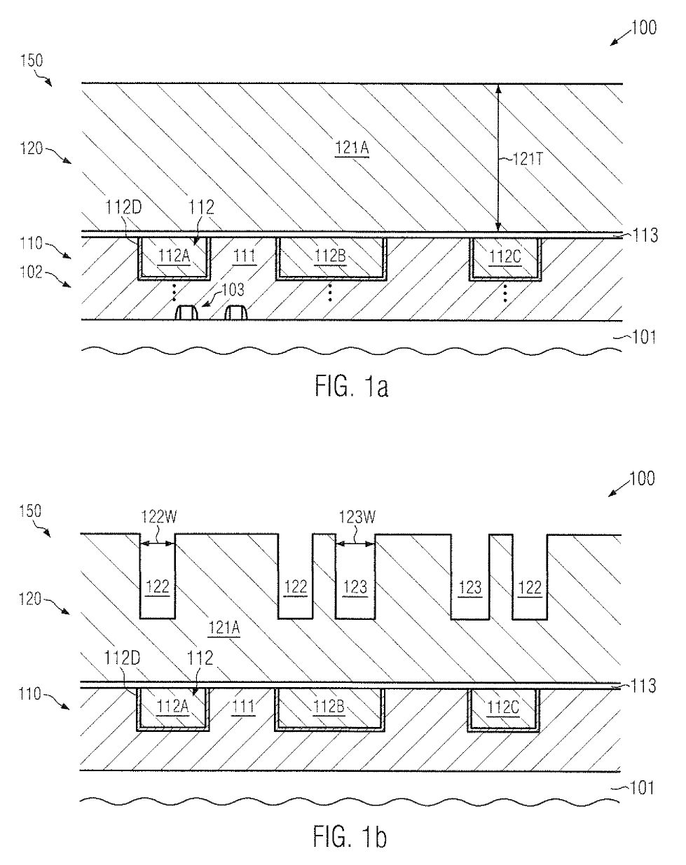

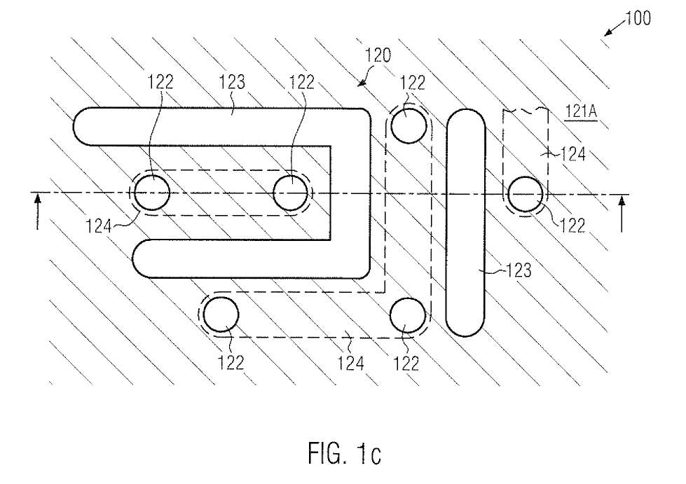

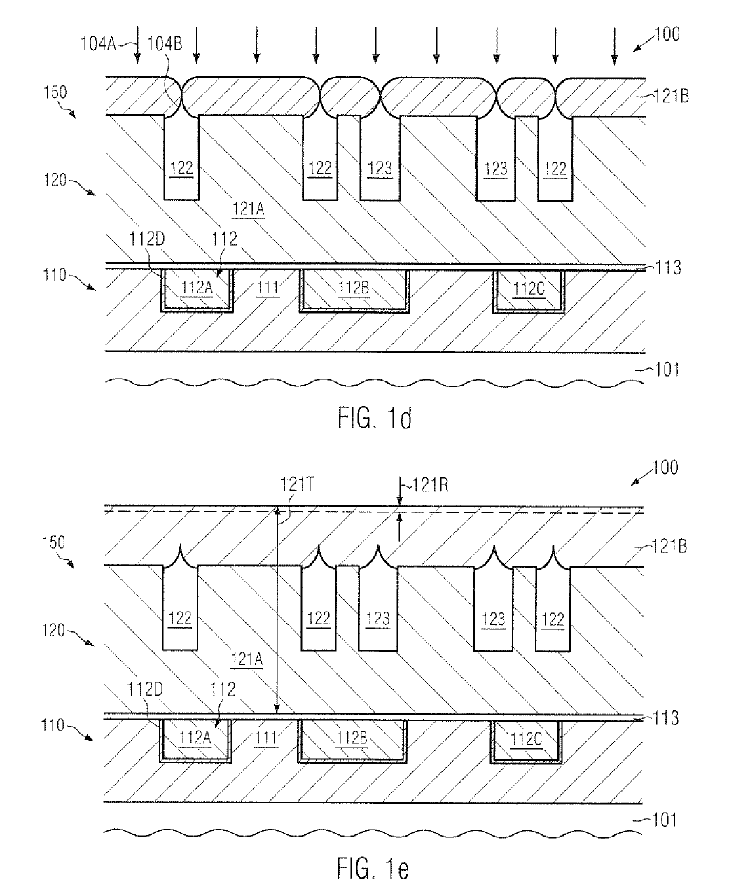

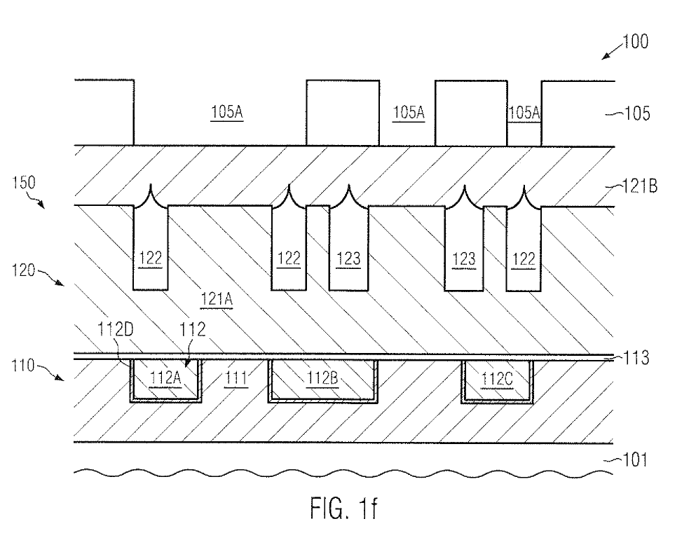

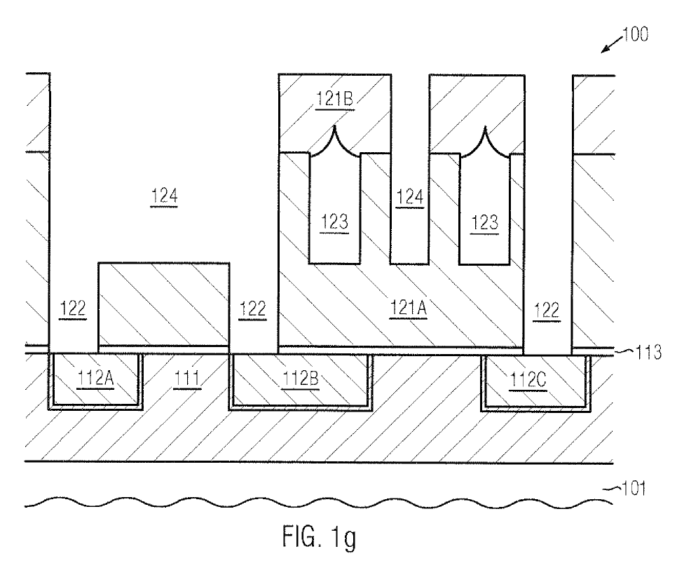

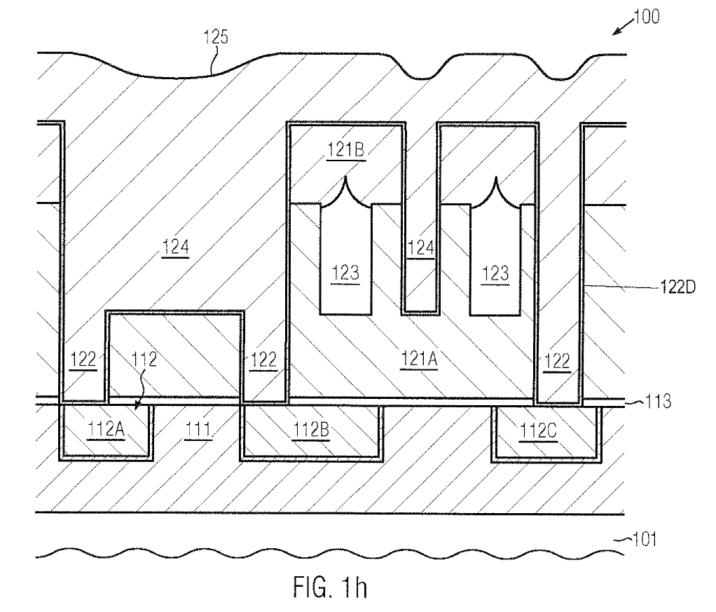

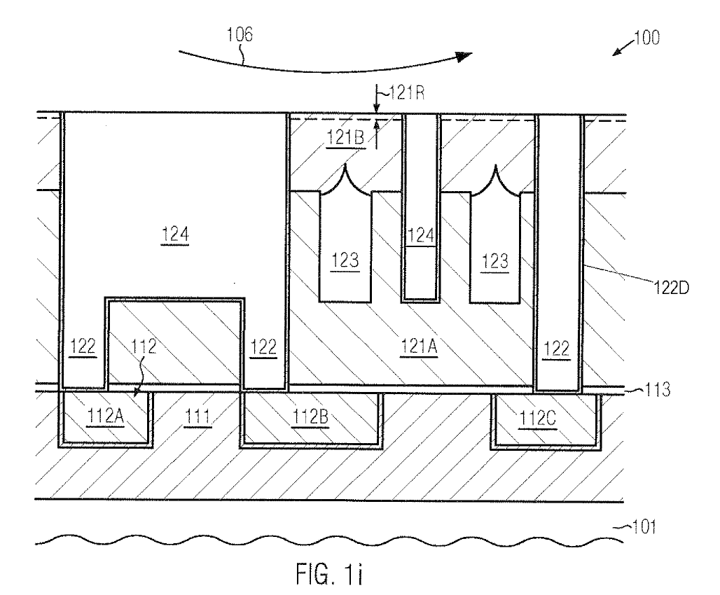

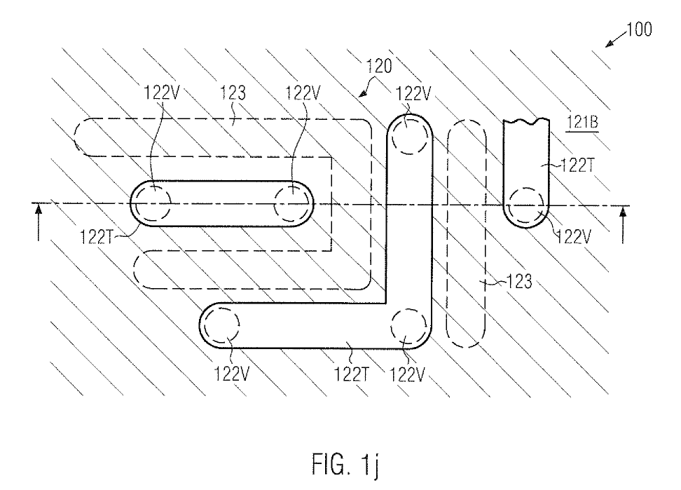

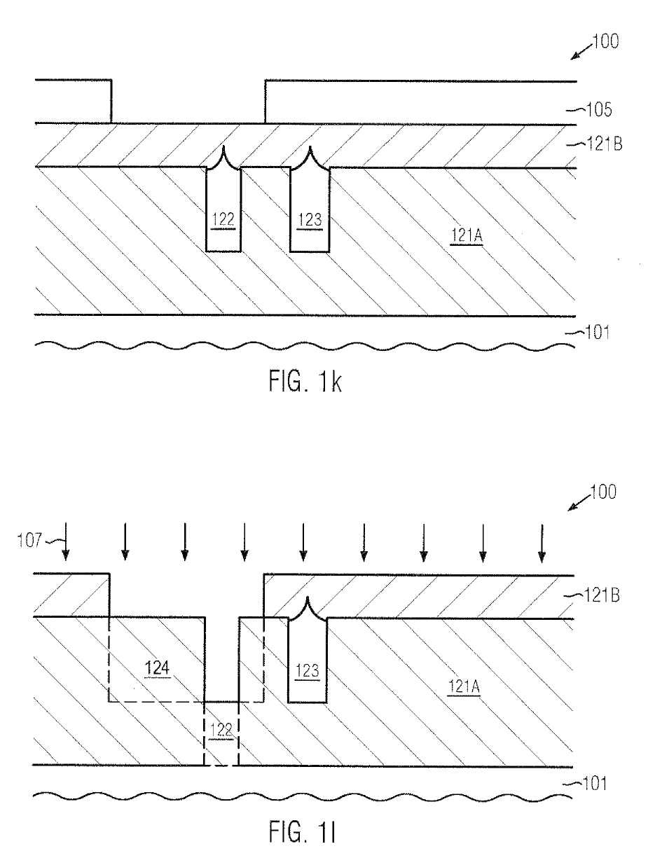

FIG. 1a schematically illustrates a cross-sectional view of a microstructure device 100 which, in the embodiment shown, may represent an integrated circuit including a plurality of circuit elements, such as transistors, capacitors, resistors and the like. In this case, the device 100 may comprise a device level 102 in which a plurality of circuit elements 103, such as transistors and the like, may be formed above a substrate 101. For example, the substrate 101 may represent a semiconductor substrate, an insulating substrate having formed thereon an appropriate semiconductor layer in and above which are formed the circuit elements 103. In other cases, a buried insulating layer may be provided, at least locally, between a corresponding semiconductor layer and the substrate 101, thereby defining a silicon-on-insulator (SOI) architecture. The circuit elements 103, when provided in the form of transistor elements, may comprise components such as a gate electrode when field effect transistors are considered, which may be formed on the basis of a critical dimension of approximately 50 nm and less, such as 30 nm and less, in highly sophisticated semiconductor devices. Moreover, the device level 102 may comprise a contact structure (not shown) which may be considered as an interface between the circuit elements 103 and a metallization system 150. As previously explained, typically, one or more electrical connections may be associated with each of the circuit elements 103, which may therefore require a plurality of metallization layers for devices having a high packing density in the device level 102 in order to establish the electrical connections for the elements 103 according to the circuit layout under consideration. For convenience, two metallization layers 110 and 120 of the metallization system 150 are illustrated, wherein it should be appreciated, however, that below and/or above the metallization layers 110, 120 one or more additional metallization layers may be provided, depending on the overall complexity of the device 100. For any of these additional metallization layers, the same criteria may apply as will be described later on with reference to the metallization layers 110 and 120.

The metallization layer 110 may comprise a dielectric material 111 of appropriate characteristics in view of mechanical stability, overall permittivity and the like. For example, the dielectric material 111 may comprise, at least partially, a low-k dielectric material, which is to be understood as a material having a dielectric constant of 3.0 and less. However, as previously explained, very sophisticated dielectric materials, which may typically have a significantly reduced mechanical strength, may not be provided if the overall characteristics of the material 111 are compatible with the performance criteria of the metallization layer 110. In other cases, reduced overall permittivity is required and appropriately positioned air gaps (not shown) may be provided in the dielectric material 111, as will be described in more detail with reference to the metallization layer 120. The metallization layer 110 may further comprise metal lines 112, which may be comprised of a highly conductive “core material” 112A, 112B, 112C, for instance in the form of copper, copper alloy and the like, wherein a conductive barrier material 112D may provide reliable confinement of the conductive core materials 112A, 112B, 112C. For example, tantalum, tantalum nitride or a combination thereof, or any other materials, may be efficiently used as a conductive barrier material. Furthermore, a capping layer or etch stop layer 113 may be formed above the dielectric material 111 and the metal lines 112, wherein the layer 113 may, depending on the circumstances, additionally act as a barrier material for confining the conductive core materials 112A, 112B, 112C. For instance, silicon nitride, nitrogen-containing silicon carbide, silicon carbide and the like may provide copper diffusion hindering capabilities and may frequently be used as a cap layer for copper-based metal lines. In other cases, the metal regions 112 may comprise a conductive cap material for which a plurality of metal alloys are well established in the art. In this case, the copper-confining capabilities of the layer 113 may be less critical.

The metallization layer 120 may comprise, in this manufacturing stage, a first dielectric material 121A, such as any appropriate dielectric material having the desired characteristics with respect to permittivity, mechanical strength and the like. As previously discussed, the dielectric material 121A may be less sensitive, for instance with respect to its mechanical characteristics, compared to sophisticated ultra low-k dielectric materials, which are frequently used in sophisticated devices in view of reducing parasitic capacitance. In the present embodiment, the dielectric constant may be less critical since the overall permittivity of the metallization layer 120 may be adjusted on the basis of corresponding air gaps still to be formed, wherein superior mechanical characteristics of the dielectric material 121A in combination with a further material still to be formed may provide an overall enhanced mechanical stability of the metallization layer 120, while nevertheless providing the desired low overall permittivity. For instance, the dielectric material 121A may represent any dielectric material having a dielectric constant of 2.7 and higher, such as 3.0 and higher, since, typically, a moderately low dielectric constant is associated with a corresponding reduced mechanical strength of the dielectric material. For example, the dielectric material 121A may be comprised of silicon dioxide, for instance in the form of a fluorine-doped material, or any other material composition providing the desired stability. It should be appreciated, however, that the material 121A may also represent a sophisticated dielectric material with a reduced permittivity, while nevertheless enhanced performance may be obtained by providing air gaps, which may, in conventional approaches, require the usage of more sophisticated dielectrics having a significantly more pronounced sensitivity with respect to mechanical and chemical stress conditions, which may be encountered during the further processing of the corresponding microstructure device. The dielectric material 121A may be provided with an appropriate thickness 121T which, in combination with a thickness of a further dielectric material still to be formed, may result in a target thickness of the metallization layer 120.

The microstructure device 100 as shown in FIG. 1a may be formed on the basis of the following process techniques. After forming the corresponding circuit elements 103 in the device level 102, which may include sophisticated manufacturing techniques in accordance with the technology standard under consideration, a corresponding contact structure (not shown) may be formed so as to electrically connect to the circuit elements 103. For this purpose, well-established dielectric materials, such as silicon dioxide, silicon nitride and the like, may be deposited and patterned in order to obtain respective contact openings which may subsequently be filled with an appropriate conductive material. Thereafter, the metallization system 150 may be formed, for instance by depositing the dielectric material 111 and forming therein the metal regions 112 on the basis of process techniques, as will also be described with reference to the metallization layer 120. It should be appreciated that appropriate air gaps (not shown) may also be provided in the metallization layer 110, if required, wherein similar process techniques may be used as will be described in the context of the metallization layer 120. Thereafter, the cap layer or etch stop layer 113 may be formed on the basis of well-established deposition techniques. Next, the dielectric material 121A may be formed, for instance by plasma enhanced chemical vapor deposition (CVD), thermally activated CVD, spin-on techniques and the like, in order to obtain the material of the layer 121A with the desired characteristics. For instance, a plurality of well-established deposition recipes are available for silicon dioxide, silicon oxynitride, silicon nitride, silicon dioxide-based materials including additional components for reducing the overall permittivity, polymer materials and the like. Thereafter, the first dielectric layer 121A may be patterned on the basis of any appropriate patterning technique in order to provide openings in the material 121A that may correspond to via openings and air gaps in accordance with the overall device requirements. For example, the material 121A may be patterned by using photolithography techniques in which an etch mask may be formed on the basis of a resist mask, wherein if required any additional materials, such as anti-reflective coating (ARC) materials and the like, may be provided. It should be appreciated that any such materials may be provided in the material 121A depending on the overall process strategy. For instance, during the deposition of the material 121A, one or more material layers may be formed as final layers of a corresponding layer stack in order to provide the desired functionality. In other cases, respective ARC materials may be provided temporarily during the corresponding lithography process. In other illustrative embodiments, the patterning of the material 121A may be accomplished on the basis of imprint techniques in which the material 121A may initially be provided in a state of low viscosity and may be brought into contact with a corresponding nano stamp in order to obtain a desired pattern of openings in the material 121A, which may subsequently be cured and may thus, after removal of the nano stamp, include the desired pattern.

FIG. 1b schematically illustrates the microstructure device 100 after the above-described process sequence and after the removal of any etch mask when a photolithography process has been used for patterning the dielectric material 121A. As illustrated, a plurality of openings 122, 123 are formed in the material 121A so as to extend to a certain depth that may be appropriate for completing respective via openings, i.e., the openings 122, in a subsequent etch process for forming corresponding trenches of the metallization layer 120. That is, the via openings 122 may be further patterned so as to extend to the respective ones of the metal lines 112 of the metallization layer 110 in a subsequent etch process. In addition to the via openings 122, corresponding air gaps 123 may be appropriately positioned in the dielectric material 121A so as to reduce overall permittivity of the metallization layer 120. Consequently, the air gaps 123 may be formed during the patterning process for forming the via openings 122, thereby not contributing to additional process complexity compared to conventional strategies. It should be appreciated that the openings 122 and 123 may be formed on the basis of the same critical dimension, such as a width 122W, 123W, while, in other cases, the width 123W may be selected differently with respect to the width 122W, if considered appropriate for the specific layout of metal regions in the metallization layer 120. Moreover, the shape of the air gaps 123 may be different from the corresponding shape of the via openings so that any desired configuration of “air channels” may be incorporated into the metallization layer 120.

FIG. 1c schematically illustrates a top view of a portion of the metallization layer 120 according to illustrative embodiments. As illustrated, the plurality of via openings 122 may be provided in accordance with the circuit layout of the device 100, while respective air gaps 123, for instance in the form of channels or trenches, may be positioned such that a reduced overall permittivity may be obtained between neighboring metal lines that are still to be formed and that are indicated as dashed lines 124 in FIG. 1c. Consequently, the parasitic capacitance between neighboring metal lines 124 may be efficiently reduced, while at the same time a moderately high mechanical stability may be achieved in the metallization layer 120.

FIG. 1d schematically illustrates the microstructure device 100 in a cross-sectional view of a further advanced manufacturing stage. As illustrated, the device 100 is exposed to a deposition ambient 104A that is designed to deposit a second dielectric material 121B in such a manner that the openings 122, 123 may be covered or closed without unduly reducing the interior volume of the openings 122, 123. The deposition ambient 104A may represent a chemical vapor deposition process performed on the basis of process parameters which may result in the creation of significant overhangs 104B, which may result in a rapid closure of the openings 122, 123, while significant deposition of the material 121B within the openings 122, 123 may be suppressed. Corresponding deposition recipes may be readily available or may be established on the basis of test runs and the like. In other cases, the deposition ambient 104A may be established on the basis of spin-on techniques, in combination with an appropriate viscous state of the material 121B, which may result in a coverage or closing of the openings 122, 123 while substantially not penetrating the interior of these openings. It should be appreciated that a certain degree of deposition into the openings 122, 123 may be tolerable since, in the openings 122, the corresponding material may be removed in a subsequent further patterning process, while a corresponding minimal reduction of the volume of the air gaps 123 may not significantly influence the overall permittivity. Consequently, the second dielectric material 121B may be provided as any appropriate material, which may act as an interlayer dielectric material of the metallization layer 120, while at the same time the material 121B may act as a cover or closure of the openings 122, 123 by appropriately selecting corresponding process parameters for any appropriate deposition technique, such as CVD, spin-on processes and the like. In some illustrative embodiments, the material 121B may be provided in the form of two or more sub-layers, for instance when a material composition has a desired deposition characteristic so as to reliably seal the openings 122, 123 without significant deposition into the inner volume thereof, while subsequently the deposition may be continued on the basis of a different material in order to adjust the overall characteristics of the interlayer dielectric material of the metallization layer 120. In still other illustrative embodiments, the material 121B may be provided so as to have similar characteristics as the material 121A when a substantially continuous and homogeneous behavior of the interlayer dielectric material of the metallization layer 120 is desired. For instance, the materials 121B, 121A may be provided on the basis of substantially the same material composition so as to obtain a desired high mechanical stability. In other cases, the material 121B, or at least a portion thereof, may be provided so as to act as an ARC material and/or as a hard mask material in further patterning sequence. Consequently, in addition to covering the openings 122, 123, a high degree of flexibility in adjusting the overall material characteristics of the metallization layer 120 may also be accomplished by performing the deposition step 104A.

FIG. 1e schematically illustrates the microstructure device 100 after completing deposition of the material 121B. As illustrated, the material 121B may be provided with a thickness that is appropriately selected in order to obtain a combined target thickness 121T according to device and process requirements. That is, the first and second dielectric materials 121A, 121B may be provided so as to obtain the desired target thickness of the metallization layer 120 wherein, if required, any material removal 121R during the further processing may also be taken into consideration. For instance, during a subsequent patterning process and the removal of any excess material to be filled into the via openings 122 and corresponding metal trenches, the layer 121B may act as a stop layer, which may cause a certain degree of material removal. Thus, the material 121B may be provided with a thickness that provides for a reliable sealing of the air gaps 123, even if a certain degree of material removal, such as indicated by 121R, may occur during the further processing. As previously discussed with reference to FIG. 1d, the material 121B may be comprised of any desired type of material, at least partially, in order to adjust the final desired material characteristics. For instance, an upper portion of the material 121B may be selected so as to act as an etch stop layer, a CMP stop layer and the like while, in other cases, an ARC material may be included, if desired. Moreover, the material 121B, or at least a portion thereof, may act as a hard mask material that may be patterned on the basis of lithography techniques and which may then act as an etch mask during the further processing of the device 100.

FIG. 1f schematically illustrates the device 100 with an etch mask 105 formed above the dielectric material 121B. The etch mask 105 may represent a resist mask, possibly in combination with other materials, such as a hard mask material, an ARC material and the like. In other cases, the material 121B, or at least a portion thereof, may act as a hard mask material, an ARC material and the like, as previously discussed. The etch mask 105 may comprise appropriate openings 105A, which correspond to the position and the lateral size of corresponding metal lines to be formed in the metallization layer 120, for instance according to the layout as illustrated in FIG. 1c. The etch mask 105 may be formed on the basis of well-established lithography techniques. Thereafter, anisotropic etch recipes may be applied to etch the materials 121B and 121A in order to transfer the pattern of the etch mask 105 into the combined dielectric material 121B, 121A, thereby also increasing the depth of the via openings 122 so as to extend to the corresponding metal regions 112 of the metallization layer 110.

FIG. 1g schematically illustrates the microstructure device 100 after the above-described etch process and after removal of the etch mask 105. Thus, as illustrated, the via openings 122 may extend down to the corresponding metal regions 112, while the trenches 124 may also be formed in accordance with the required circuit layout in the material 121B and, in the embodiment shown, also in a portion of the material 121A. During the corresponding etch sequence, the via openings 122 may increasingly be exposed when etching through the material 121B and, during the further advance of the etch front within the material 121A, the depth of the openings 122 may continuously be increased until the etch stop layer 113 may reliably stop the etch front in the openings 122, thereby avoiding undue exposure of the metal regions 122 to the etch ambient. Thus, after a desired depth of the trenches 124 is achieved, the etch stop layer 113 may be opened on the basis of specifically selected etch parameters, thereby exposing a portion of the metal regions 112. On the other hand, the air gaps 123 may remain covered by the material 121B due to the presence of the etch mask 105 (FIG. 1f). During the etch process or thereafter, the etch mask 105 may be removed and, if required, respective wet chemical cleaning recipes may be applied so as to prepare exposed surface areas for the deposition of a metal-containing material. It should be appreciated that, due to the provision of the air gaps 123, generally, a dielectric material for the layers 121B, 121A may be selected that may have enhanced resistance with respect to the corresponding etch processes for patterning the layers 121B, 121A for removing the etch mask 105 and for performing respective cleaning processes. Hence, significantly reduced etch damage may be observed compared to other approaches in which highly sensitive ultra low-k dielectric materials may typically be used to obtain the desired overall low permittivity.

FIG. 1h schematically illustrates the microstructure device 100 in a further advanced manufacturing stage in which a highly conductive metal, such as copper, a copper alloy, silver and the like, may be formed in the openings 122, 124 and above the dielectric material 121B, wherein, if required, a conductive barrier material 122D, such as tantalum, tantalum nitride and the like, may be formed on surface areas of the materials 121B, 121A and the metal regions 112. The barrier material 122D may be formed on the basis of any appropriate deposition technique, such as physical vapor deposition, chemical vapor deposition, atomic layer deposition, electroless deposition processes and the like. Similarly, the material 125 may be deposited, for instance, by electrochemical deposition techniques, possibly in combination with deposition of an appropriate seed material, depending on the overall process strategy. Irrespective of the deposition technique used, the air gaps 123 may reliably be covered by the material 121B, thereby maintaining the integrity of the air gaps 123 during the entire processing.

FIG. 1i schematically illustrates the device 100 during a removal process 106, which may comprise electrochemical etch processes, electrochemical polishing processes, chemical mechanical polishing and the like, in order to remove any excess material of the layer 125 (FIG. 1h) and also remove portions of the barrier material 122D. As previously discussed, during the removal process 106, a portion of the material 121B may be removed, for instance as indicated by 121R, wherein, however, a desired integrity of the air gaps 123 may be maintained by appropriately selecting an initial thickness of the material 121B, as previously explained. After the removal process 106, corresponding metal lines 122T are formed in accordance with the desired circuit layout and respective vias 122V provide an electrical connection between corresponding trenches or lines 122T and the metal regions 112 of the metallization layer 110 (see FIG. 2j).

FIG. 1j schematically illustrates a top view of the device 100 after the removal process 106. As shown, the metal lines 122T may be separated by the corresponding air gaps 123, which are illustrated in dashed lines, since these air gaps are actually not visible, thereby significantly reducing the parasitic capacitance between adjacent metal lines 122T. On the other hand, the materials 121B and 121A may provide sufficient mechanical stability with respect to the further processing of the device 100 and in view of the operation of the device 100. That is, less critical dielectric materials may be used, at least for one of the materials 121B, 121A while nevertheless providing an overall low permittivity due to the presence of the air gaps 123. As previously discussed, the overall design of a corresponding metallization level, such as the metallization layer 120, may be established in such a manner that at least critical signal paths may be separated by corresponding air gaps 123 in order to reduce signal propagation delay. In other cases, corresponding air gaps 123 may be readily implemented into existing circuit layouts so that, except for any lithography masks or imprint stamps for forming the vias of the corresponding metallization level, no further changes may be required. Consequently, the air gaps 123 may be dimensioned and positioned without any additional process steps during the patterning of the via openings, while the subsequent closure or covering of the openings may be accomplished by an additional deposition step to obtain the desired target height of the interlayer dielectric material. During the deposition, additional functionality may also be imparted to the interlayer dielectric material, for instance with respect to etch stop capabilities, CMP stop capabilities, ARC functionality, hard mask functionality and the like. The material may be appropriately provided to accomplish the desired coverage of via openings and the air gaps, wherein corresponding material characteristics may also be appropriately selected. If enhanced surface topography may be desired, an additional planarization step may be introduced after the deposition of the dielectric material 121B, thereby further enhancing performance of a subsequent lithography step. Thereafter, the further processing may be continued by using well-established lithography techniques, thereby maintaining a high degree of compatibility with conventional process strategies.

FIG. 1k schematically illustrates the device 100 in which the material 121b may be provided to act as a hard mask material, which may be patterned on the basis of the etch mask 105 that is provided in the form of a resist material. Consequently, less restrictive constraints may be imposed on the entire lithography process since a moderately thin resist material may be used to first pattern the material 121B, which may then be used as a hard mask material for etching into and through the dielectric material 121A.

FIG. 1l schematically illustrates the device 100 during a corresponding etch process 107, which may be performed after patterning the material 121B and removing the resist mask 105. Thus, based on the patterned material 121B, corresponding trenches 124 may be formed in the material 121A, thereby also increasing the depth of the via openings 122, while the air gaps 123 are still reliably covered by the material 121B. In this case, at least an upper portion of the material 121B may be provided in the form of material having a high etch resistivity with respect to the process 107. For instance, the material 121B may comprise silicon nitride, nitrogen-containing silicon carbide, silicon carbide and the like, which are well-established materials and which may have a high etch selectivity with respect to other materials, such as silicon dioxide and the like. After the etch process 107, the further processing may be continued as previously described, i.e., a conductive material may be filled into the openings 124, 122 in order to obtain the metal lines 122T and the vias 122V (FIG. 1j).

As a result, the present disclosure provides microstructure devices and respective manufacturing techniques in which air gaps may be provided with a desired shape and position without requiring additional efforts during the patterning of the corresponding interlayer dielectric material. For this purpose, the air gaps may be formed together with corresponding via openings during a common patterning sequence, which may include photolithography in combination with etch techniques, imprint techniques and the like, followed by the deposition of a cap material in order to reliably cover and thus close the corresponding openings. In a further patterning process, the via openings may be reopened during a corresponding etch process for additionally generating the trenches for the metal lines of the metallization level under consideration. Thus, a very efficient overall manufacturing process flow may be accomplished since no additional process steps may be required for defining the position and size of the air gaps, while enhanced flexibility in designing the overall material characteristics may be achieved due to the deposition of the dielectric material for closing or sealing the via openings and air gaps.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a via opening and an air gap in a first dielectric layer of a metallization system of a semiconductor device in a common etch process;
depositing a second dielectric layer so as to cover said via opening and said air gap;
increasing a depth of said via opening so as to extend to a conductive region formed below said first dielectric layer while maintaining said air gap; and
filling said via opening with a metal-containing material.

2. The method of claim 1, wherein increasing a depth of said via opening comprises forming a trench at least in said second dielectric layer so as to connect to said via opening.

3. The method of claim 1, further comprising removing excess material of said metal-containing material while maintaining at least a portion of said second dielectric layer that covers said air gap.

4. The method of claim 1, wherein said first and second dielectric layers represent dielectric materials of a metallization layer of said metallization system.

5. The method of claim 1, wherein said air gap and said via opening are formed on the basis of substantially the same critical dimension.

6. The method of claim 1, wherein said air gap comprises a trench-shaped portion.

7. The method of claim 1, wherein at least one of said first and second dielectric layers is comprised of a non-low-k dielectric material.

8. The method of claim 1, wherein said first and second dielectric layers are comprised of substantially the same material composition.

9. The method of claim 1, wherein increasing a depth of said via opening comprises patterning said second dielectric layer on the basis of a resist mask to define trench openings in said second dielectric layer and using said patterned second dielectric layer as an etch mask for etching said first dielectric layer.

10. The method of claim 1, wherein said second dielectric layer comprises a copper-confining material.

11. A method, comprising:
forming an etch mask above a dielectric material of a metallization layer of a microstructure device, said dielectric material comprising a first cavity covered by a first portion of said dielectric material and a second cavity covered by a second portion of said dielectric material, said etch mask exposing said first portion and covering said second portion of said dielectric material;
selectively opening said first cavity by using said etch mask; and
filling said first cavity with a metal-containing material.

12. The method of claim 11, further comprising removing an excess portion of said metal-containing material without exposing said second cavity.

13. The method of claim 11, wherein selectively opening said first cavity comprises forming a trench in said dielectric material so as to connect to said first cavity.

14. The method of claim 13, wherein selectively opening said first cavity further comprises increasing a depth of said first cavity so as to extend to a conductive region formed below said metallization layer.

15. The method of claim 11, further comprising forming said first and second cavities in a first part of said dielectric material in a common etch process.

16. The method of claim 15, wherein forming said first and second cavities further comprises depositing a second part of said dielectric material above said first and second cavities while maintaining at least a portion of an inner volume of said first and second cavities.

17. The method of claim 16, further comprising planarizing said second part of said dielectric material prior to forming said etch mask.

18. The method of claim 11, wherein at least a part of said dielectric material is provided as a material having a dielectric constant of approximately 2.7 or higher.

19. A microstructure device, comprising:
a first dielectric layer of a metallization layer;
a second dielectric layer formed on said first dielectric layer;
a metal line formed in said second dielectric layer and extending into said first dielectric layer; and
an air gap formed in said first dielectric layer, said air gap being capped by said second dielectric layer.

20. The device of claim 19, wherein said air gap and said metal line have substantially the same width.

21. The device of claim 20, wherein said width is approximately 100 nm or less.

22. The device of claim 20, wherein said second dielectric layer is comprised of a material having a dielectric constant of approximately 2.7 or more.

23. The device of claim 19, further comprising transistor elements having a gate length of approximately 30 nm or less.
